(19) United States
(12) Patent Application Publication
(10) Pub. No.: US 2025/0048574 A1
(43) Pub. Date: Feb. 6, 2025

(54) INVERTER, AND, PHOTOVOLTAIC AND ENERGY STORAGE SYSTEM

(71) Applicant: Sungrow (Shanghai) Co., Ltd., Shanghai (CN)

(72) Inventors: Fanghui Zhang, Hefei (CN); Haiyang Yu, Hefei (CN); Feng Li, Hefei (CN)

(73) Assignee: Sungrow (Shanghai) Co., Ltd., Shanghai (CN)

(21) Appl. No.: 18/399,375

(22) Filed: Dec. 28, 2023

(30) Foreign Application Priority Data
Aug. 3, 2023 (CN) 202322079796.1

(51) Int. Cl. H05K 5/02; H02M 1/00

(52) U.S. Cl. CPC H05K 5/0247; H02M 1/00

(57) ABSTRACT

The application discloses an inverter and a photovoltaic and energy storage system. The inverter includes a first cabinet configured for being fixed on a mounting surface and a second cabinet configured for being fixed on the mounting surface, where the first cabinet is provided with a first connection terminal, the second cabinet is provided with a second connection terminal, the first connection terminal and the second connection terminal are configured for plugging along a direction that the first cabinet moves to the mounting surface, and the first connection terminal and the second connection terminal are plugged with each other when the first cabinet is located on the mounting surface. The inverter described above simplifies assembly of the first cabinet and the second cabinet, thereby simplifying mounting of the inverter.

### CROSS REFERENCE TO RELATED APPLICATIONS

This application claims the priorities to Chinese patent application No. 202322079796.1, titled “INVERTER, AND, PHOTOVOLTAIC AND ENERGY STORAGE SYSTEM”, filed with the China National Intellectual Property Administration Aug. 3, 2023, the entire disclosure of which is hereby incorporated by reference.

### FIELD

The application relates to the technical field of a power electronic device, and in particular to an inverter and a photovoltaic and energy storage system.

### BACKGROUND

In order to meet a standard requirement for a certain field, an inverter includes a first cabinet and a second cabinet. In the conventional inverter, an assembly of the first cabinet and the second cabinet is complicated, resulting in a cumbersome mounting of the inverter. In addition, it is not convenient to replace and maintain the first cabinet and the second cabinet, which is not conducive to disassembly and maintenance of the inverter.

In summary, how to design the inverter to simplify the assembly of the first cabinet and the second cabinet and facilitate the mounting of the inverter is an urgent problem to be solved by those skilled in the art.

### SUMMARY

In view of this, an object of the application is to provide an inverter and a photovoltaic and energy storage system to simplify assembly of the first cabinet and the second cabinet, thereby simplifying mounting of the inverter.

In order to achieve the above object, the following technical solution is provided according to the application.

An inverter includes:
a first cabinet, which is configured for being fixed on a mounting surface;
a second cabinet, which is configured for being fixed on the mounting surface;
and the first cabinet is provided with a first connection terminal, the second cabinet is provided with a second connection terminal, the first connection terminal and the second connection terminal are configured for plugging along a direction in which the first cabinet moves to the mounting surface, and the first connection terminal and the second connection terminal are plugged with each other when the first cabinet is located on the mounting surface.

In an embodiment, the first cabinet includes a first hanging plate and a first cabinet main body, and the first hanging plate is configured for being fixed on the mounting surface, the first hanging plate is provided with a hanging fixing position for hanging and fixing the first cabinet main body, and the first connection terminal is arranged on the first cabinet main body;
and the first cabinet moves to a direction of the mounting surface, specifically, the first cabinet main body moves to a direction of the hanging fixing position;
the first cabinet is located on the mounting surface, specifically, the first hanging plate is fixed on the mounting surface and the first cabinet main body is located at the hanging fixing position.

In an embodiment, the first hanging plate further has a hanging position only for hanging the first cabinet main body, and the first cabinet main body is movable between the hanging position and the hanging fixing position;
the first connection terminal and the second connection terminal are configured for plugging along a direction in which the first cabinet main body moves from the hanging position to the hanging fixing position.

In an embodiment, one of the first cabinet main body and the first hanging plate is provided with a slideway hole, and the other of the first cabinet main body and the first hanging plate is provided with a first hook which is in sliding fit with the slideway hole;
and when one end of the slideway hole is in contact with the first hook, the first cabinet main body is in the hanging position, and when the other end of the slideway hole is in contact with the first hook, the first cabinet main body is in the hanging fixing position.

In an embodiment, when the first cabinet main body is in the hanging fixing position, the first cabinet main body is detachably and fixedly connected with the first hanging plate; and the first connection terminal is detachably plugged with the second connection terminal.

In an embodiment, one of the first cabinet and the second cabinet is provided with a positioning post and the other of the first cabinet and the second cabinet is provided with a positioning hole; and the positioning post is fitted with the positioning hole and is in contact with a bottom wall of the positioning hole, and an axial direction of the positioning post is parallel to a plugging direction of the first connection terminal and the second connection terminal.

In an embodiment, when the first cabinet is located on the mounting surface, the first cabinet is fixedly connected with the second cabinet by a fastener, and an axial direction of the fastener is parallel to the plugging direction of the first connection terminal and the second connection terminal.

In an embodiment, the first cabinet is provided with a first mounting post, and the second cabinet is provided with a second mounting post;
and the first mounting post and the second mounting post each is provided with a mounting hole for mounting the fastener; one of the first mounting post and the second mounting post is provided with a positioning hole, and the other of the first mounting post and the second mounting post is fitted with the positioning hole and is in contact with the bottom wall of the positioning hole.

In an embodiment, one of the first cabinet and the second cabinet is provided with a guide post and the other of the first cabinet and the second cabinet is provided with a guide hole; and the guide post and the guide hole are configured for guiding and matching in the plugging direction of the first connection terminal and the second connection terminal.

In an embodiment, the first cabinet includes a first cabinet main body, on which the first connection terminal is arranged; and the second cabinet includes a second cabinet main body, on which the second connection terminal is arranged;
and one of the first cabinet main body and the second cabinet main body is embedded in the other; or the first cabinet main body is entirely located outside the second cabinet main body, and the second cabinet main body is entirely located outside the first cabinet main body.

In an embodiment, when one of the first cabinet main body and the second cabinet main body is embedded in the other, the first cabinet main body has a cabinet connecting part for mounting the first connection terminal, and both the cabinet connecting part and the first connection terminal are embedded in the second cabinet main body, and the cabinet connecting part and the second cabinet main body are fixedly connected with each other.

In an embodiment, the second cabinet main body includes:
a second cabinet housing for fixing on the mounting surface, and the second connection terminal is arranged in the second cabinet housing, the cabinet connecting part is fixedly connected with the second cabinet housing, and a side, away from the mounting surface, of the second cabinet housing is provided with an mounting port for fixedly connecting the cabinet connecting part and the second cabinet housing; and
a second cabinet cover plate, and the second cabinet cover plate is fixed on the second cabinet housing, and the second cabinet cover plate closes the mounting port.

In an embodiment, the second cabinet housing and the second cabinet cover plate are detachably connected with each other, and the cabinet connecting part and the second cabinet housing are detachably connected with each other.

In an embodiment, the first cabinet includes a first cabinet housing and a first cabinet cover plate, and one side of the first cabinet housing is opposite to the mounting surface, and the other side of the first cabinet housing is fixedly connected with the first cabinet cover plate;
and the first connection terminal is arranged in the first cabinet housing, and the first cabinet housing is provided with a first wiring hole for a first cable to pass through and a first blocking member for sealing the first wiring hole.

In an embodiment, the second cabinet includes a second cabinet main body and a second hanging plate, and the second hanging plate is configured for being fixed on the mounting surface, and the second cabinet main body is configured for being hung and fixed on the second hanging plate;
and the second connection terminal is arranged on the second cabinet main body, and the second cabinet main body is provided with a second wiring hole for a second cable to pass through and a second blocking member for sealing the second wiring hole.

In an embodiment, the first cabinet includes a first hanging plate and a first cabinet main body, and the first hanging plate is configured for being fixed on the mounting surface and is provided with a hanging fixing position for hanging and fixing the first cabinet main body, and the first connection terminal is arranged on the first cabinet main body;
the first cabinet main body moves to a direction of the mounting surface, specifically, the first cabinet main body moves to a direction of the hanging fixing position;
the first cabinet main body is located on the mounting surface, specifically, the first hanging plate is fixed on the mounting surface and the first cabinet main body is located at the hanging fixing position;
and the second hanging plate and the first hanging plate have an integrated structure or a separated structure.

In an embodiment, the plugging direction of the first connection terminal and the second connection terminal is perpendicular to the mounting surface;
and/or the first cabinet and the second cabinet are sequentially distributed in a vertical direction;
and/or the first connection terminal and the first cabinet are hermetically connected with each other, the second connection terminal and the second cabinet are hermetically connected with each other, and the first connection terminal and the second connection terminal are hermetically connected with each other.

Based on the inverter described above, a photovoltaic and energy storage system is provided according to the application, including the inverter as described in any one of the above.

A method for mounting the inverter provided according to the application is as follows: firstly fixing the second cabinet on the mounting surface; then moving the first cabinet to the mounting surface; the first connection terminal of the first cabinet is getting close to the second connection terminal of the second cabinet during the movement. The first connection terminal is plugged to the second connection terminal when the first cabinet is moved to the mounting surface, that is, the first connection terminal is plugged to the second connection terminal when the first cabinet is located on the mounting surface; and finally the first cabinet is fixed on the mounting surface.

According to the above method, he first connection terminal is plugged to the second connection terminal when the first cabinet is moved to the mounting surface, and there is no need to plug the first connection terminal and the second connection terminal separately, thus effectively simplifying the assembly of the first cabinet and the second cabinet, and simplifying the mounting of the inverter.

### BRIEF DESCRIPTION OF THE DRAWINGS

For more clearly illustrating embodiments of the application or the technical solutions in the conventional technology, drawings referred to for describing the embodiments or the conventional technology will be briefly described hereinafter. Apparently, the drawings in the following description are only examples of the application, and for those skilled in the art, other drawings may be obtained based on the drawings provided without any creative efforts.

FIG. 1 is an axonometric view of an inverter provided according to an embodiment of the application;

FIG. 2 is a side view of an inverter provided according to an embodiment of the application;

FIG. 3 is a top view of an inverter provided according to an embodiment of the application;

FIG. 4 is a schematic view showing an internal structure of an inverter provided according to an embodiment of the application;

FIG. 5 is a schematic view showing another internal structure of an inverter provided according to an embodiment of the application;

FIG. 6 is a front view of a first cabinet of an inverter provided according to an embodiment of the application;

FIG. 7 is a side view of a first cabinet of an inverter provided according to an embodiment of the application;

FIG. 8 is a bottom view of a first cabinet of an inverter provided according to an embodiment of the application;

FIG. 9 is a schematic structural view showing a structure in FIG. 8, in which a first cover plate and a first blocking member are removed;

FIG. 10 is a rear view of a first cabinet of an inverter provided according to an embodiment of the application;

FIG. 11 is a schematic structural view showing a structure in FIG. 10, in which a first connection terminal is removed;

FIG. 12 is an axonometric view of a hanging plate of an inverter provided according to an embodiment of the application;

FIG. 13 is a front view of a hanging plate of an inverter provided according to an embodiment of the application;

FIG. 14 is a front view of a first connection terminal of an inverter provided according to an embodiment of the application;

FIG. 15 is a side view of a first connection terminal of an inverter provided according to an embodiment of the application;

FIG. 16 is a bottom view of a first connection terminal of an inverter provided according to an embodiment of the application;

FIG. 17 is a front view of a second cabinet of an inverter provided according to an embodiment of the application;

FIG. 18 is a side view of a second cabinet of an inverter provided according to an embodiment of the application;

FIG. 19 is a top view of a second cabinet of an inverter provided according to an embodiment of the application;

FIG. 20 is a rear view of a second cabinet of an inverter provided according to an embodiment of the application;

FIG. 21 is a front view of a second cabinet housing of an inverter provided according to an embodiment of the application;

FIG. 22 is a top view of a second cabinet housing of an inverter provided according to an embodiment of the application;

FIG. 23 is a rear view of a second cabinet housing of an inverter provided according to an embodiment of the application;

FIG. 24 is an axonometric view of a second hanging plate of an inverter provided according to an embodiment of the application;

FIG. 25 is a front view of a second hanging plate of an inverter provided according to an embodiment of the application;

FIG. 26 is a front view of a cabinet bracket of an inverter provided according to an embodiment of the application;

FIG. 27 is a side view of a cabinet bracket of an inverter provided according to an embodiment of the application;

FIG. 28 is a top view of a cabinet bracket of an inverter provided according to an embodiment of the application;

FIG. 29 is a front view of a second connection terminal of an inverter provided according to an embodiment of the application;

FIG. 30 is a side view of a second connection terminal of an inverter provided according to an embodiment of the application;

FIG. 31 is a top view of a second connection terminal of an inverter provided according to an embodiment of the application;

FIG. 32 is a schematic structural view of an inverter provided according to an embodiment of the application, in which a first hanging plate and a second hanging plate are mounted on a mounting surface;

FIG. 33 is a schematic structural view of an inverter provided according to an embodiment of the application, in which a second cabinet main body is mounted to a second hanging plate;

FIG. 34 is a schematic structural view of an inverter provided according to an embodiment of the application, in which a first cabinet main body is mounted to a first hanging plate and is in a hanging position;

FIG. 35 is a top view of a structure shown in FIG. 34;

FIG. 36 is a schematic view showing an internal structural of an inverter provided according to an embodiment of the application, in which a first cabinet main body is mounted to a first hanging plate and is in a hanging position.

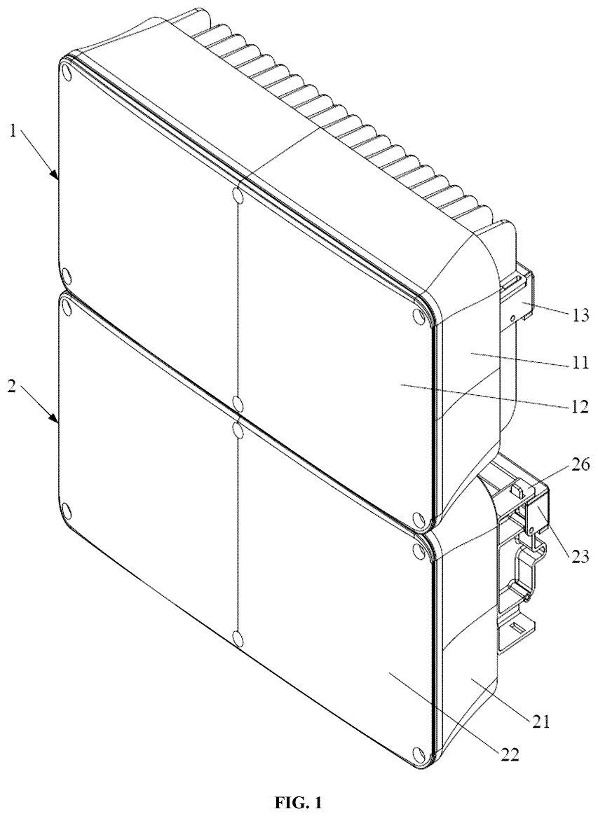

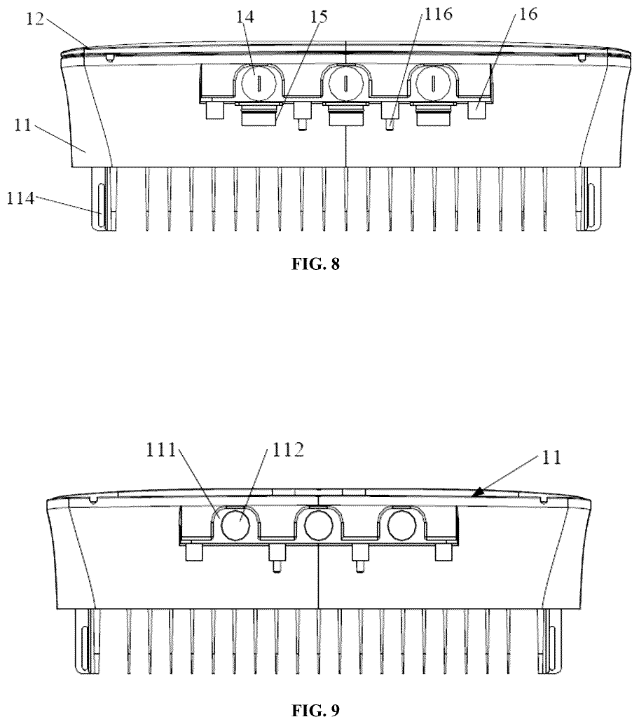

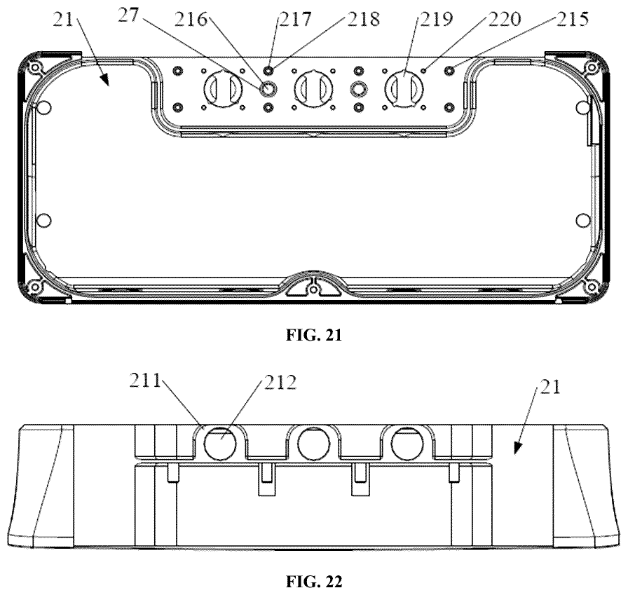

Reference numerals in FIG. 1 to FIG. 36 are listed as follows:
1 first cabinet, 2 second cabinet, 3 mounting surface;
11 first cabinet housing, 12 first cabinet cover plate, 13 first hanging plate, 14 first blocking member, 15 first connection terminal, 16 first mounting post;
111 first blocking member mounting surface, 112 first wiring hole, 113 first mounting hole, 114 slideway hole, 115 first hanging plate fixing hole, 116 guide post, 117 positioning hole, 118 positioning hole bottom wall, 119 first connection terminal mounting hole, 120 first connection terminal fixing hole;
131 first connecting hole, 132 first reinforcing plate, 133 slideway surface, 134 first hook, 135 second connecting hole;
151 first terminal body, 152 first error-prevention assembling rib, 153 terminal pin, 154 pin mounting hole, 155 first end face sealing ring, 156 interface sealing ring, 157 sealing groove, 158 first cable;
21 second cabinet housing, 22 second cabinet cover plate, 23 second hanging plate, 24 second blocking member, 25 second connection terminal, 26 cabinet bracket;
211 second blocking member mounting surface, 212 second wiring hole, 213 bracket mounting hole, 214 guide member, 215 second mounting post, 216 guide hole, 217 second mounting hole, 218 post end face, 219 second connection terminal mounting hole, 220 second connection terminal fixing hole;
231 third connecting hole, 232 second reinforcing plate, 233 fourth connecting hole, 234 second hook;
251 second terminal body, 252 second error-prevention assembling rib, 253 terminal socket, 254 terminal inserting hole, 255 second end face sealing ring, 256 second cable;
261 cabinet mounting surface, 262 cabinet mounting hole, 263 supporting surface, 264 second hanging plate mounting hole, 265 hanging hole;
01 hanging fixing position, 02 hanging position.

### DETAILED DESCRIPTION OF THE EMBODIMENTS

The technical solutions in the embodiments of the application is described clearly and completely hereinafter in conjunction with the drawings in the embodiments of the application. Apparently, the described embodiments are only a part of the embodiments of the application, rather than all embodiments. Any other embodiments obtained by those skilled in the art based on the embodiments in the application without any creative effort fall within the protection scope of the application.

Following is a clear and complete description of the technical solutions of embodiments of the present application with reference to the accompanying drawings in the present application. The terminology used in the following examples is only for the purpose of describing specific embodiments, and is not intended as a limitation of the present application. As used in the specification and appended claims of the present application, the singular expressions “a”, “an”, “the”, “such”, “this” and “this one” are intended to also include expressions such as “one or more” unless the context clearly indicates the contrary. It should also be understood that in the embodiment of the present application, the term “one or more” refers to one, two or more; the term “and/or” describes an association relationship of related objects and indicates there may be three kinds of relationships, for example, A and/or B may indicate three cases, such as A exists alone, A and B exist at the same time, and B exists alone. In each case, a quantity of A may be one or more, and a quantity of B may be one or more. The symbol “/” generally indicates that a former object and a latter object are associated by an “or” relationship.

References to “one embodiment” or “embodiments” and the like described in this specification indicate that a particular feature, structure, or characteristic described in connection with the embodiment is included in one or more embodiments of the present application. Thus, the phrases “in one embodiment”, “in some embodiments”, “in other embodiments” and “in another embodiments” appearing in different places in this specification do not necessarily all refer to the same embodiment, but mean “one or more but not all embodiments” unless otherwise emphasized. The terms “including”, “comprising”, “having” and their variations all mean “including but not limited to” unless otherwise specifically emphasized.

“Multiple” in the embodiment of the present application refers to two or more. It should be noted that in the description of the embodiment of the present application, words such as “first” and “second” are only used for the purpose of distinguishing descriptions, and cannot be understood as indicating or implying relative importance, nor can they be understood as indicating or implying order.

“Parallel” and “vertical” referred to in the present application are “generally parallel” and “generally vertical” in actual operation. “Generally parallel” can be understood as parallel with certain errors. Similarly, “generally vertical” can be understood as vertical with certain errors.

In the conventional technology, an inverter includes a first cabinet and a second cabinet, where the first cabinet accommodates an inverter main machine, and the second cabinet accommodates a converging protection component and components with other functions.

There are two main ways to mount the first cabinet and the second cabinet.

First, the second cabinet is attached to the first cabinet, so that the second cabinet cannot be mounted separately, which is not conducive to mounting, disassembly and maintenance of the inverter.

Secondly, the second cabinet may be mounted separately, and the second cabinet is arranged separately outside the first cabinet. In this way, it is needed to manually plug and unplug the cable inside the second cabinet, which leads to cumbersome and inconvenient disassembly and assembly, and is not conducive to maintenance. In addition, the first cabinet and the second cabinet are fixedly connected by fasteners, which are located on both sides of the first cabinet and the second cabinet, leading to inconvenient disassembly and assembly of the fasteners, and causing it less convenient for the disassembly and assembly of the first cabinet and the second cabinet.

Therefore, in the conventional technology, the assembly of the first cabinet and the second cabinet is complicated, resulting in cumbersome mounting of the inverter. In addition, it is not convenient to replace and maintain the first cabinet and the second cabinet, which is not conducive to the disassembly and assembly and maintenance of the inverter.

In order to solve the above technical problems, an inverter is provided according to an embodiment of the application to simplify the assembly of the first cabinet and the second cabinet, thus simplifying the mounting of the inverter.

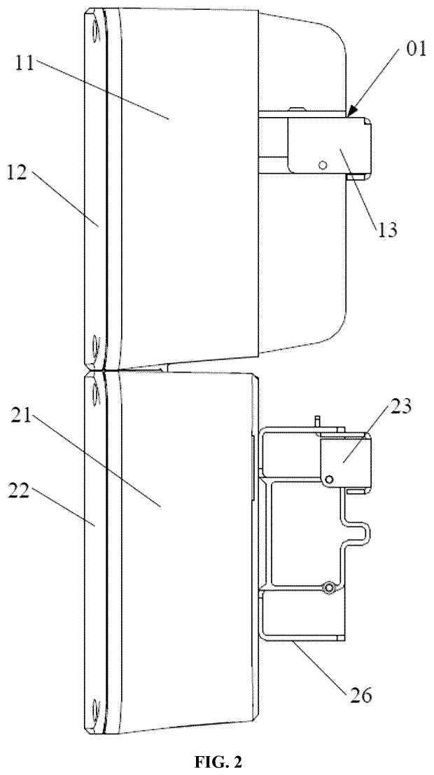

As shown in FIG. 1 and FIG. 2, the inverter provided according to an embodiment of the application includes a first cabinet 1 and a second cabinet 2.

In some embodiments, one of the first cabinet 1 and the second cabinet 2 is configured for accommodating an inverter main machine and the other of the first cabinet 1 and the second cabinet 2 is configured for accommodating a converging protection component. In other embodiments, the first cabinet 1 and the second cabinet 2 may also be configured for accommodating other components, which is not limited in the embodiment of the application.

The first cabinet 1 and the second cabinet 2 are both configured for being fixed on a mounting surface. The mounting surface may be a surface of a wall or other object, and a specific form of the mounting surface is not limited in the embodiment of the application.

The first cabinet 1 and the second cabinet 2 are sequentially distributed in a vertical direction, for example, the first cabinet 1 is located at a top end of the second cabinet 2 or the first cabinet 1 is located at a bottom end of the second cabinet 2. Also, the first cabinet 1 and the second cabinet 2 may also be distributed in other direction, which is not limited in the embodiment of the application.

The second cabinet 2 can be mounted on the mounting surface separately. The entire second cabinet 2 may be located inside or outside the first cabinet 1. In order to simplify the disassembly and assembly of the first cabinet 1 and the second cabinet 2, the whole second cabinet 2 may be located outside the first cabinet 1, so that it facilitates mounting the second cabinet 2 separately.

The first cabinet 1 includes a first hanging plate 13 and a first cabinet main body (not numbered in the drawings). In some embodiments, the first cabinet main body includes a first cabinet housing 11 and a first cabinet cover plate 12, and one side of the first cabinet housing 11 is connected to the first hanging plate 13, and the other side of the first cabinet housing 11 is fixedly connected to the first cabinet cover plate 12. It can be understood that the first cabinet housing 11 is located between the first hanging plate 13 and the first cabinet cover plate 12.

In other embodiments, the first cabinet cover plate 12 may be located at other positions of the first cabinet housing 11, and the first cabinet main body may have other structures, which is not limited in the embodiment of the application.

The first hanging plate 13 is configured to be fixed on the mounting surface. As shown in FIG. 13, in some embodiments, the first hanging plate 13 is provided with a first connecting hole 131, and a fastener passing through the first connecting hole 131 can fix the first hanging plate 13 on the mounting surface. The fastener described above may be an anchor bolt or a bolt or the like, which are not limited by the embodiment of the application.

The number of the first connecting holes 131 is provided based on actual situation, which is not limited in the embodiment of the application.

In order to facilitate disassembly and assembly, the first hanging plate 13 may be configured to be detachably fixed on the mounting surface. In this case, the fastener passing through the first connecting hole 131 may be configured to detachably fix the first hanging plate 13 on the mounting surface.

The first hanging plate 13 has a hanging fixing position for hanging and fixing the first cabinet main body. It can be understood that the first cabinet main body is fixed at the hanging fixing position after the inverter has been mounted. As shown in FIG. 2 and FIG. 3, the first cabinet housing 11 is in the hanging fixing position 01.

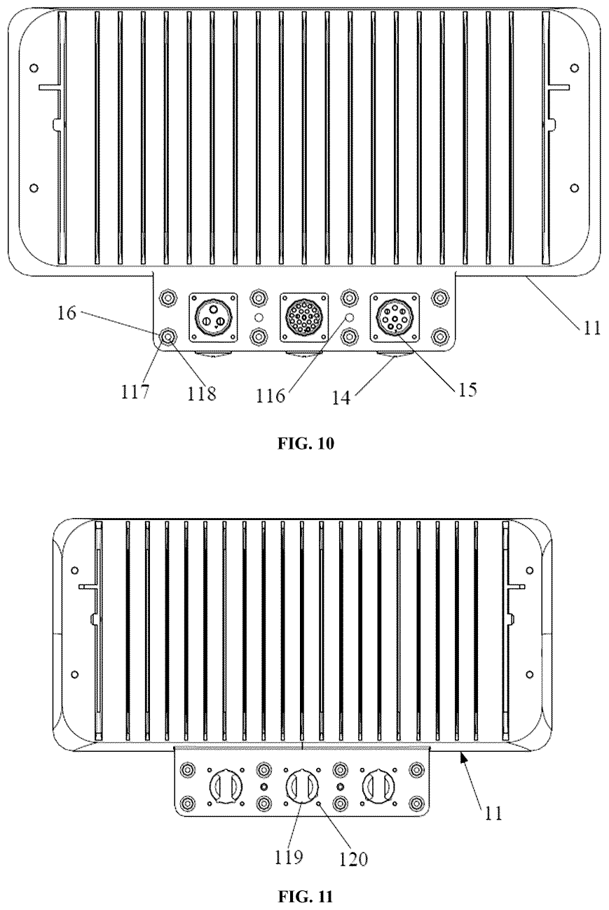

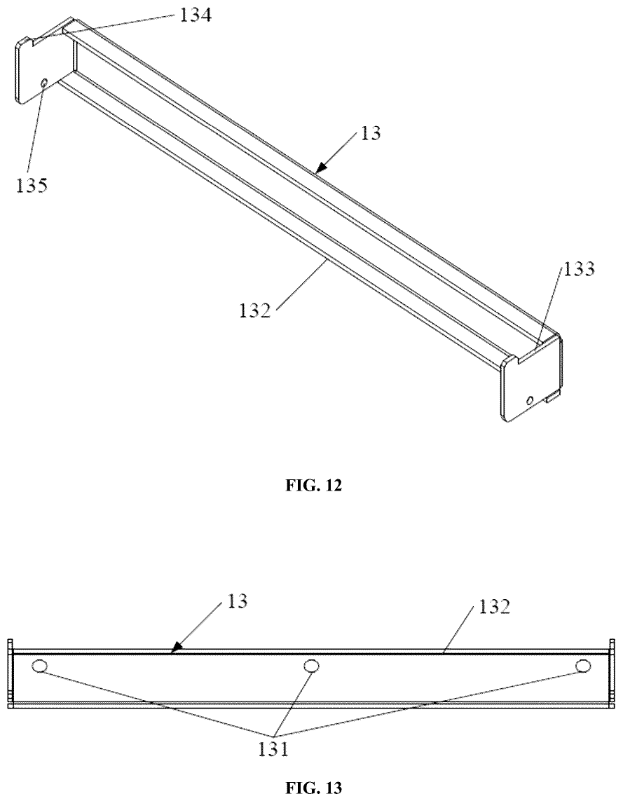

In order to facilitate the first cabinet main body to be fixed at the hanging fixing position 01, as shown in FIG. 12, each of two ends of the first hanging plate 13 is provided with a second connecting hole 135, and as shown in FIG. 7, the first cabinet main body is provided with a first hanging plate fixing hole 115 corresponding to the second connecting hole 135, and the fastener is fixedly connected with the first cabinet main body and the first hanging plate 13 through the first hanging plate fixing hole 115 and the second connecting hole 135.

In order to improve a supporting strength of the first hanging plate 13, as shown in FIG. 12 and FIG. 13, the first hanging plate 13 is provided with a first reinforcing plate 132. The number of the first reinforcing plate 132 is at least one, and the specific number of the first reinforcing plate 132 is determined based on the actual situation, which is not limited in the embodiment of the application.

The first reinforcing plate 132 may be arranged based on the actual situation. In order to effectively improve the strength, the first reinforcing plate 132 may extend from one end of the first hanging plate 13 to the other end of the first hanging plate 13.

In order to facilitate the second cabinet 2 being fixed on the mounting surface, as shown in FIG. 1 and FIG. 2, the second cabinet 2 includes a second cabinet main body (not shown in the drawings) and a second hanging plate 23, and the second hanging plate 23 is configured for being fixed on the mounting surface, and the second cabinet main body is configured for being hung and fixed on the second hanging plate 23.

As shown in FIG. 1 and FIG. 2, in some embodiments, the second cabinet main body includes a second cabinet housing 21 and a second cabinet cover plate 22, and one side of the second cabinet housing 21 is hung and fixed on the second hanging plate 23, and the other side of the second cabinet housing 21 is fixedly connected to the second cabinet cover plate 22. It should be noted that the second cabinet housing 21 is located between the second hanging plate 23 and the second cabinet cover plate 22.

Also, the second cabinet cover plate 22 may be located at other positions of the first cabinet housing 21, and the second cabinet main body may have other structures, which is not limited in the embodiment.

In some other embodiments, the second cabinet housing 21 may also be directly fixed on the mounting surface. In this case, the second cabinet 2 does not include the second hanging plate 23.

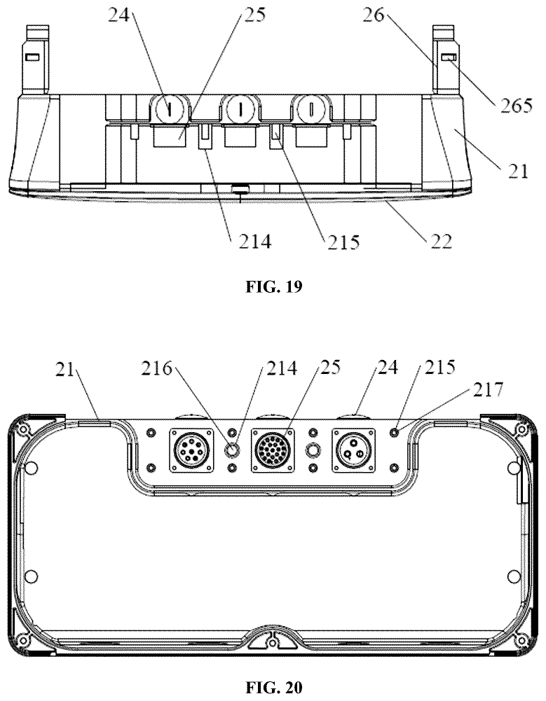

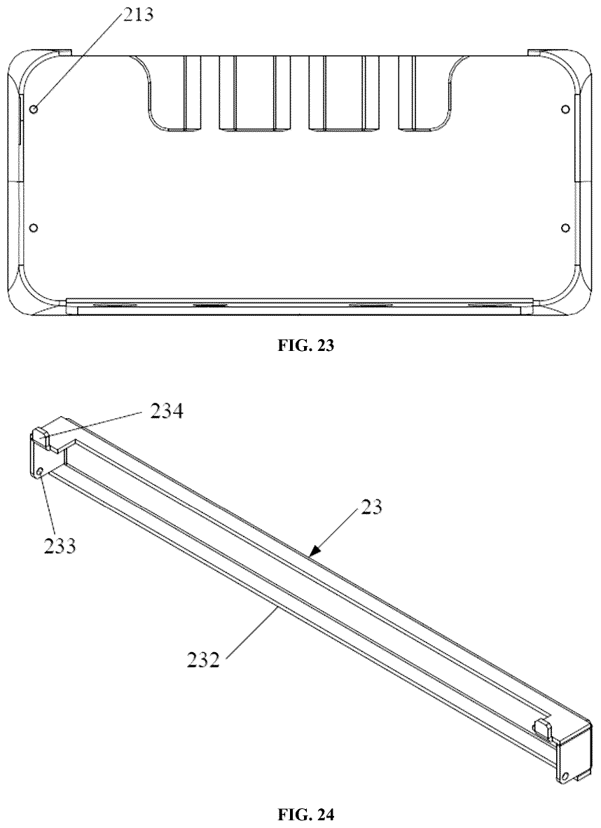

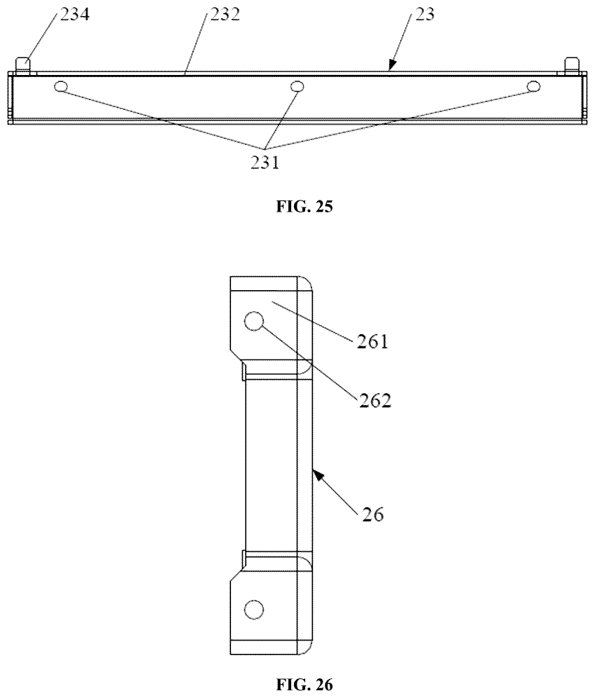

In the above structure, one of the second cabinet main body and the second hanging plate 23 is provided with a second hook, and the other of the second cabinet main body and the second hanging plate 23 is provided with a hanging hole, and the second hook is hung in the hanging hole. As shown in FIG. 24 and FIG. 25, the second hook 234 is arranged on the second hanging plate 23. Accordingly, as shown in FIG. 19, the hanging hole 265 is arranged on the second cabinet main body.

The second hanging plate 23 is configured to be fixed on the mounting surface. As shown in FIG. 25, in some embodiments, the second hanging plate 23 is provided with a third connecting hole 231, and a fastener passing through the third connecting hole 231 can fix the second hanging plate 23 on the mounting surface. The number of the third connecting hole 231 may be provided based on the actual situation, which is not limited in this embodiment.

In order to facilitate disassembly and assembly, the second hanging plate 23 may be configured to be detachably fixed on the mounting surface. In this case, the fastener passing through the third connecting hole 231 may be configured for detachably fixing the second hanging plate 23 on the mounting surface.

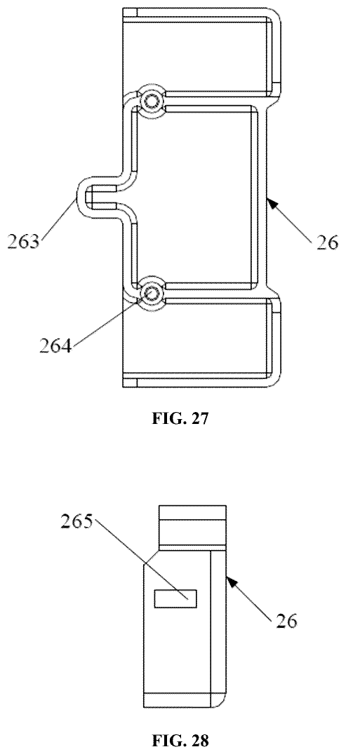

In order to facilitate fixedly connecting the second cabinet main body and the second hanging plate 23, as shown in FIG. 24, each of two ends of the second hanging plate 23 is provided with a fourth connecting hole 233, and as shown in FIG. 27, the second cabinet main body is provided with a second hanging plate mounting hole 264 corresponding to the fourth connecting hole 233. In this way, the fastener fixedly connects the second cabinet main body and the second hanging plate 23 through the second hanging plate mounting hole 264 and the fourth connecting hole 233.

In order to improve a supporting strength of the second hanging plate 23, as shown in FIG. 24 and FIG. 25, the second hanging plate 23 is provided with a second reinforcing plate 232. The number of the second reinforcing plate 232 is at least one, and the specific number of the second reinforcing plate 232 may be determined based on the actual situation, which is not limited in the embodiment of the application.

The second reinforcing plate 232 may be distributed based on the actual situation. In order to effectively improve the strength, the second reinforcing plate 232 may be configured to extend from one end of the second hanging plate 23 to the other end of the second hanging plate 23.

In some embodiments, in order to simplify the structure, the second hanging plate 23 and the first hanging plate 13 may be configured as an integrated structure. In this way, the stability of the whole inverter is also improved. In this case, both the first cabinet main body and the second cabinet main body may be mounted separately.

In some other embodiments, the second hanging plate 23 and the first hanging plate 13 may be configured as separated structures. In this way, both the first cabinet 1 and the second cabinet 2 may be mounted separately.

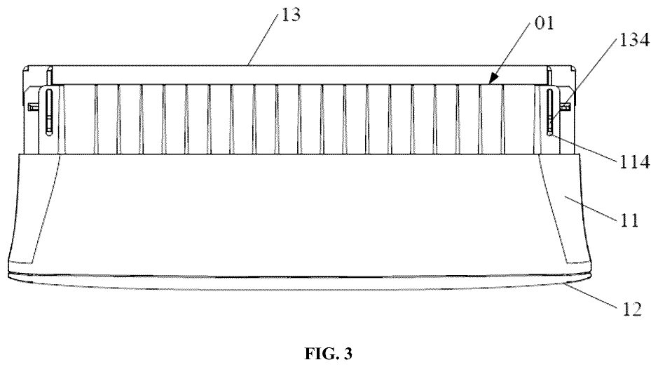

As shown in FIG. 4, the first cabinet main body is provided with a first connection terminal 15, and the second cabinet 2 is provided with a second connection terminal 25. It can be understood that the first connection terminal 15 is hermetically connected to the first cabinet main body, the second connection terminal 25 is hermetically connected to the second cabinet 2, and the first connection terminal 15 is configured for being hermetically connected to the second connection terminal 25.

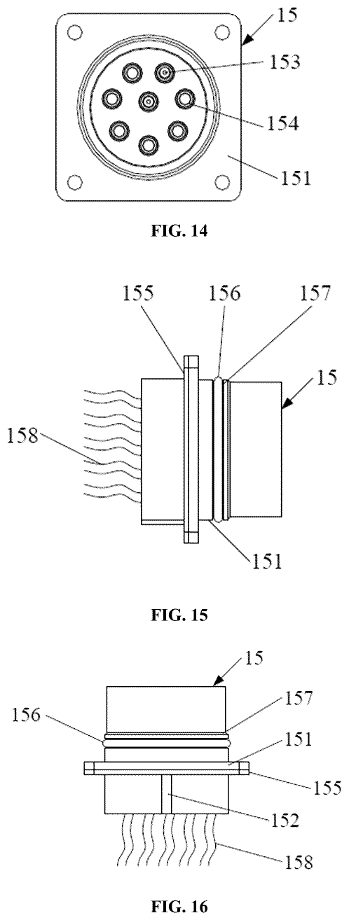

As shown in FIG. 14 to FIG. 16, the first connection terminal 15 includes a first terminal body 151, and one end of the first terminal body 151 has a terminal pin 153 for plugging with the second connection terminal 25, and the other end of the first terminal body 151 leads out a first cable 158.

It can be understood that the first cable 158 is electrically connected with the terminal pin 153 by crimping or welding. The first cable 158 passes through a first wiring hole 112 and enters the first cabinet main body.

In order to facilitate mounting the terminal pin 153, the first terminal body 151 is provided with a pin mounting hole 154, and the terminal pin 153 is arranged in the pin mounting hole 154.

A circumferential outer wall of the first terminal body 151 is provided with a first error-prevention assembling rib 152, so that the first connection terminal 15 is prevented from being wrongly mounted, and efficiency of mounting the first connection terminal 15 is improved.

In order to facilitate a sealed connection between the first connection terminal 15 and the first cabinet main body, the first terminal body 151 may be mounted with a first end face sealing ring 155. In order to facilitate positioning the first end face sealing ring 155 along an axial direction of the first connection terminal 15, the first terminal body 151 is provided with a positioning shoulder for positioning the first end face sealing ring 155. Also, the first connection terminal 15 and the first cabinet main body may also be sealed by other means, which is not limited in the embodiment of the application.

In order to facilitate a sealed connection between the first connection terminal 15 and the second connection terminal 25, the first terminal body 151 is provided with a sealing groove 157 and an interface sealing ring 156 arranged in the sealing groove 157. In this way, the first connection terminal may be hermetically connected with the second connection terminal 25 through the interface sealing ring 156. Also, the interface sealing ring 156 may also be arranged on the second connection terminal 25. Alternatively, the first connection terminal 15 may be hermetically connected with the second connection terminal 25 by other means, which is not limited in the embodiment of the application.

As shown in FIG. 8 and FIG. 9, in order to facilitate introducing the first cable 158 into the first cabinet main body, the first cabinet main body has a first wiring hole 112 for the first cable 158 to pass through and a first blocking member 14 for sealing the first wiring hole 112. For example, the first blocking member 14 is in a threaded fit with the first wiring hole 112, and the first blocking member 14 is hermetically connected to the first cabinet main body with its own sealing member, or the first blocking member 14 is hermetically connected to the first cabinet main body through the fastener. Also, the first blocking member 14 may also be configured to seal the first wiring hole 112 in other ways, which is not limited in the embodiment of the application.

The first blocking member 14 may be a blind cover or other components, which is not limited in the embodiment of the application.

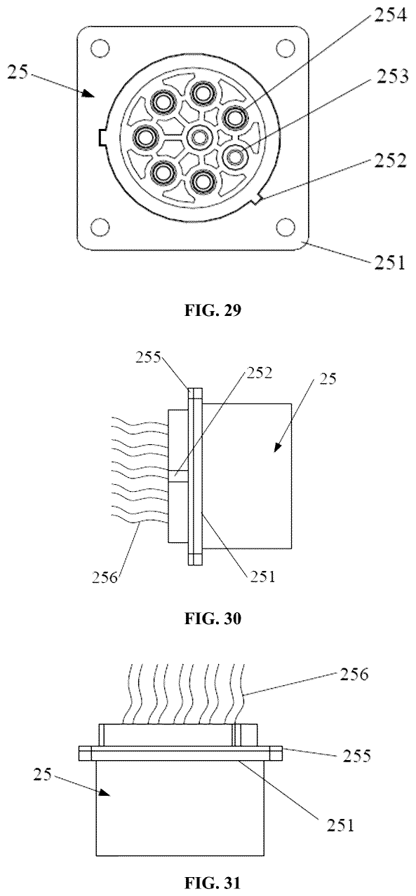

As shown in FIG. 29 to FIG. 31, the second connection terminal 25 includes a second terminal body 251. One end of the second terminal body 251 is provided with a terminal inserting hole 254, a terminal socket 253 is arranged in the terminal inserting hole 254 for inserting the terminal pin 153 of the first connection terminal 15, and a second cable 256 is led out from the other end of the second terminal body 251. It can be understood that the second cable 256 is electrically connected with the terminal socket 253 by crimping or welding to ensure an electrical connection between the second cable 256 and the terminal pin 153.

It can be understood that positions of the terminal pin 153 and the terminal socket 253 may be interchanged and are not limited to the above description.

A circumferential outer wall of the second terminal body 251 is provided with a second error-prevention assembling rib 252, so that the second connection terminal 25 is prevented from being wrongly mounted, and efficiency of mounting the second connection terminal 25 is improved.

In order to facilitate the sealed connection between the second connection terminal 25 and the second cabinet 2, the second connection terminal 25 may be mounted with a second end face sealing ring 255. In order to facilitate positioning the second end face sealing ring 255 along an axial direction of the second terminal 25, the second terminal body 251 is provided with a positioning shoulder for positioning the second end face sealing ring 255. Also, the second connection terminal 25 and the second cabinet may also be sealed by other means, which is not limited in this embodiment.

In order to facilitate introducing the second cable 256 into the second cabinet main body, as shown in FIG. 19 and FIG. 22, the second cabinet main body has a second wiring hole 212 for the second cable 256 to pass through and a second blocking member 24 for sealing the second wiring hole 212.

For example, the second blocking member 24 is in a threaded fit with the second wiring hole 212, and the second blocking member 24 is hermetically connected to the second cabinet main body with its own sealing member, or the second blocking member 24 is hermetically connected to the second cabinet main body through the fastener. Also, the second blocking member 24 may also be configured to seal the second wiring hole 212 in other ways, which is not limited in the embodiment of the application.

The second blocking member 24 may be a blind cover or other components, which is not limited in the embodiment of the application.

In the actual situation, the first connection terminal 15 and the second connection terminal 25 may also be configured as other structures, which is not limited in the embodiment of the application.

The number and arrangement of the first connection terminal 15 and the second connection terminal 25 may be determined based on the actual situation, which is not limited in the embodiment of the application.

The first connection terminal 15 is plugged to the second connection terminal 25 along a direction that the first cabinet main body moves to a hanging fixing position 01, and when the first cabinet main body is in the hanging fixing position, the first connection terminal 15 is plugged to the second connection terminal 25, and the first cabinet main body is fixedly connected with the first hanging plate 13.

It should be noted that when the first connection terminal 15 is plugged to the second terminal 25, the first connection terminal 15 is electrically connected with the second connection terminal 25. That is, the first connection terminal 15 is electrically connected with the second connection terminal 25 by plugging with each other.

For example, the direction along which the first cabinet main body moves to the hanging fixing position 01 is perpendicular to the mounting surface, and then a direction in which the first connection terminal is plugged to the second connection terminal is perpendicular to the mounting surface. Also, it is also possible that the direction along which the first cabinet main body moves to the hanging fixing position 01 is relatively inclined to the mounting surface, or is parallel to the mounting surface, which is not limited in the embodiment of the application.

A method for mounting the inverter provided in the above embodiment is as follows: firstly fixing the second cabinet 2 and the first hanging plate 13 on the mounting surface; then moving the first cabinet main body to the hanging fixing position 01, in which the first connection terminal 15 of the first cabinet main body is getting close to the second connection terminal 25 of the second cabinet 2 during the movement; plugging the first connection terminal 15 to the second connection terminal 25 when the first cabinet main body moves to the hanging fixing position 01, that is, the first connection terminal 15 is plugged to the second connection terminal 25 when the first cabinet main body is hung in the hanging fixing position of the first hanging plate 13; and finally fixedly connecting the first cabinet main body with the first hanging plate 13, so that the first cabinet main body is fixed in the hanging fixing position 01.

According to the above method, both the first cabinet 1 and the second cabinet 2 are fixed on the mounting surface, thus realizing the second cabinet 2 being mounted separately.

According to the above method, the first connection terminal 15 is plugged to the second connection terminal 25 when the first cabinet main body moves to the hanging fixing position 01, so there is no need to plug the first connection terminal 15 to the second connection terminal 25 separately, which effectively simplifies the assembly of the first cabinet 1 and the second cabinet 2, thus simplifying the mounting of the inverter.

In some embodiments, when the first cabinet main body is in the hanging fixing position 01, the first cabinet main body is detachably connected to the first hanging plate 13, and the first connection terminal 15 is detachably plugged to the second connection terminal 25. In this way, the disassembly of the first cabinet main body can be realized, and the first cabinet main body can be disassembled and assembled, as well as maintained and replaced, thus facilitating the disassembly and assembly, as well as maintenance and replacement of the inverter.

Accordingly, the second cabinet 2 may be configured to be detachably secured on the mounting surface. In this way, the disassembly of the second cabinet 2 can be realized, and the second cabinet can be disassembled and assembled, as well as maintained and replaced, thus facilitating the disassembly and assembly, as well as maintenance and replacement of the inverter.

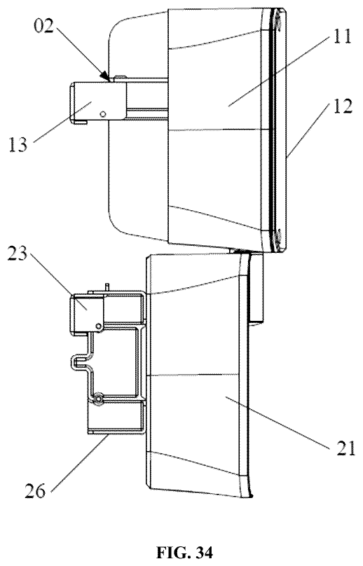

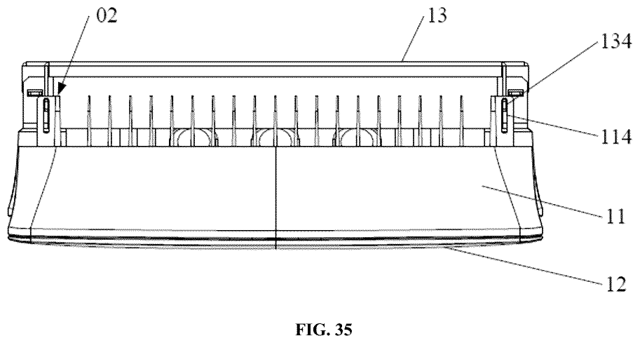

When the first cabinet main body is mounted, it is difficult to move the first cabinet main body to the hanging fixing position 01 due to a heavy weight of first cabinet main body because the components such as electronic components are arranged inside the first cabinet main body. As shown in FIG. 34 and FIG. 35, in some embodiments, the first hanging plate 13 further has a hanging position 02 only for hanging the first cabinet main body. The first cabinet main body is movable between the hanging position 02 and the hanging fixing position 01, and the first connection terminal 15 and the second connection terminal 25 are configured for plugging to each other along a direction of the first cabinet main body moving from the hanging position 02 to the hanging fixing position 01.

It should be noted that during a process of the first cabinet main body moving between the hanging position 02 and the hanging fixing position 01, the first cabinet main body is always hung on the first hanging plate 13, that is, the first cabinet main body is slidably hung on the first hanging plate 13 (before the first cabinet main body is fixed on the first hanging plate 13). In a case that the direction of the first cabinet main body moving to the hanging fixing position 01 is perpendicular to the mounting surface, the hanging position 02 is arranged away from the mounting surface than the hanging fixing position 01.

In the above embodiment, the first cabinet main body is hung on the first hanging plate 13 and moved from the hanging position 02 to the hanging fixing position 01. During the movement of the first cabinet main body, the first hanging plate 13 supports the first cabinet main body, thus facilitating the movement of the first cabinet main body. Moreover, since the first cabinet main body is hung on the first hanging plate 13, the hanging structure further provides a guidance for the movement of the first cabinet main body, which ensures the first cabinet main body to move in a predetermined direction, facilitates the first connection terminal 15 being aligned with the connection second terminal 25, and improves the reliability of the connection between the first connection terminal 15 and the second connection terminal 25.

As shown in FIG. 3 and FIG. 35, in some embodiments, one of the first cabinet main body and the first hanging plate 13 is provided with a slideway hole 114, and the other of the first cabinet main body and the first hanging plate 13 is provided with a first hook 134 which is in a sliding fit with the slideway hole 114. When one end of the slideway hole 114 is in contact with the first hook 134, the first cabinet main body is in the hanging position 02, and when the other end of the slideway hole 114 in contact with the first hook 134, the first cabinet main body is in the hanging fixing position 01. It can be understood that the first hook 134 and the slideway hole 114 are mutually guided and cooperate with each other.

The number of the first hook 134 and the slideway hole 114 can be determined based on the actual situation. In order to improve the stability, each of two ends of the first hanging plate 13 is provided with the first hook 134, and each of two ends of the first cabinet main body is provided with the slideway hole 114. Alternatively, each of the two ends of the first cabinet main body is provided with the first hook 134, and each of the two ends of the first hanging plate 13 is provided with the slideway hole 114.

As shown in FIG. 12 and FIG. 13, each of the two ends of the first hanging plate 13 is provided with the first hook 134 and a slideway surface 133, and the slideway surface 133 supports a plate where the slideway hole 114 is located.

In other embodiments, the first cabinet main body may also be hung on the first hanging plate 13 through other structures, which is not limited in the embodiment of the application.

In some embodiments, one of the first cabinet main body and the second cabinet 2 is provided with a positioning post and the other of the first cabinet main body and the second cabinet 2 is provided with a positioning hole, and the positioning post is fitted with the positioning hole and is contactable with a bottom wall of the positioning hole, and an axial direction of the positioning post is parallel to a direction in which the first connection terminal 15 is plugged with the second connection terminal 25.

In the above embodiment, a relative position of the first cabinet main body and the second cabinet 2 is ensured through a positioning cooperation of the positioning post and the positioning hole, so that the first connection terminal 15 can be ensured to be aligned with the second connection terminal 25, which thus improves the reliability of the plugging connection between the first connection terminal 15 and the connection second terminal 25. Moreover, the positioning post may be in contact with the bottom wall of the positioning hole, that is, when the first cabinet main body is in the hanging fixing position 01 (when the first connection terminal 15 is plugged to the second connection terminal 25), the positioning post is in contact with the bottom wall of the positioning hole, which ensures the first connection terminal 15 is plugged in place to the second connection terminal 25 and improves the reliability of the connection between the first connection terminal 15 and the second connection terminal 25.

The specific structure, number and distribution of the positioning holes and positioning posts are determined based on the actual situation, which is not limited in this embodiment.

In some embodiments, when the first cabinet main body is in the hanging fixing position 01, the first cabinet 1 and the second cabinet 2 are fixedly connected with each other. In this way, the stability of the whole inverter is improved, and the reliability of the connection between the first connection terminal 15 and the second connection terminal 25 is also improved. In order to facilitate disassembling the first cabinet 1 and the second cabinet 2, the first cabinet 1 may be detachably connected with the second cabinet 2 when the first cabinet main body is in the hanging fixing position 01.

In order to facilitate the first cabinet 1 being fixedly connected with the second cabinet 2, the first cabinet main body may be configured to be fixedly connected with the second cabinet 2 when the first cabinet main body is in the hanging fixing position 01.

In order to realize the disassembly of the first cabinet main body, the first cabinet main body may be configured to be detachably connected with the second cabinet 2 when the first cabinet main body is in the hanging fixing position 01.

In some embodiments, the first cabinet main body is fixedly connected with the second cabinet 2 by the fastener, and the axial direction of the fastener is parallel to the plugging direction of the first connection terminal 15 and the second connection terminal 25. In this way, the fastener improves the stability and reliability of the connection between the first connection terminal 15 and the second connection terminal 25, and also forms a reliable seal between the first connection terminal 15 and the second connection terminal 25. Since the first connection terminal 15 is hermetically connected with the first cabinet main body, and the second connection terminal 25 is hermetically connected with the second cabinet 2, it also forms a reliable seal between the first cabinet 1 and the second cabinet 2.

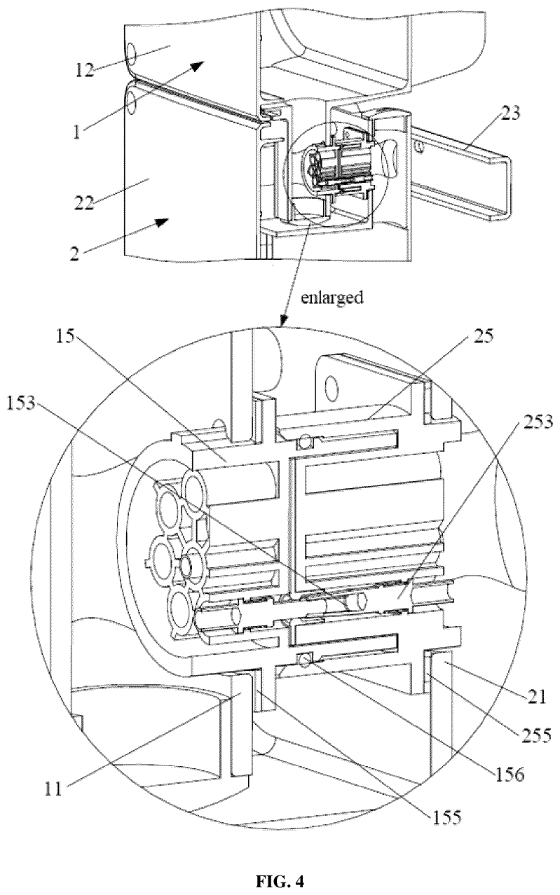

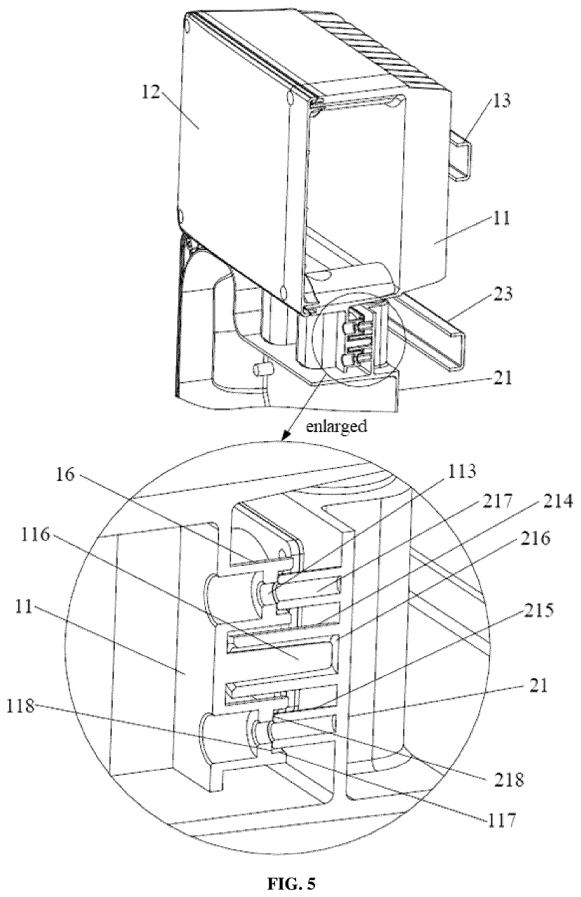

As shown in FIG. 5, in order to facilitate mounting the fastener, the first cabinet main body is provided with a first mounting post 16, and the second cabinet is provided with a second mounting post 215, and the first mounting post 16 and the second mounting post 215 each is provided with a mounting hole for mounting the fastener.

The number and distribution of the first mounting post 16 and the second mounting post 215 are determined based on the actual situation, which is not limited in the embodiment of the application.

In the above structure, one of the first mounting post 16 and the second mounting post 215 is provided with a positioning hole 117, and the other of the first mounting post 16 and the second mounting post 215 is fitted with the positioning hole 117 and in contact with the positioning hole bottom wall 118 of the positioning hole 117. In this way, a combination of positioning and fixing is realized, and the structures of the first cabinet main body and the second cabinet are effectively simplified. The first mounting post 16 or the second mounting post 215 and the positioning hole 117 realize the positioning of the first cabinet, which improves the reliability and stability of the plugging connection between the first connection terminal and second connection terminal.

For example, the first mounting post 16 is provided with a first mounting hole 113 for mounting the fastener, the second mounting post 215 is provided with a second mounting hole 217 for mounting the fastener. The first mounting post 16 is provided with the positioning hole 117, the second mounting post 215 is in a positioning fit with the positioning hole 117, and the second mounting post 215 is in contact with the positioning hole bottom wall of the positioning hole 117. It should be noted that when the first cabinet main body is in the hanging fixing position 01, the second mounting post 215 is in contact with the positioning hole bottom wall 118 of the positioning hole 117.

As shown in FIG. 5, in some embodiments, one of the first cabinet main body and the second cabinet 2 is provided with a guide post 116 and the other of the first cabinet main body and the second cabinet 2 is provided with a guide hole 216, and the guide post 116 and the guide hole 216 are configured for guiding and fitting in the plugging direction of the first connection terminal 15 and the second connection terminal 25. In this way, the first cabinet main body is ensured to move in a set direction through the guiding and fitting of the guide post 116 and the guide hole 216, thus ensuring the connection between the first connection terminal 15 and the second connection terminal 25.

It can be understood that an axial direction of the guide post 116 and an axial direction of the guide hole 216 are both parallel to the plugging direction of the first connection terminal 15 and the second connection terminal 25.

The shape, number and distribution of the guide post 116 and the guide hole 216 are determined based on the actual situation, which is not limited in this embodiment.

In order to facilitate arranging the guide hole 216, the first cabinet main body is provided with a guide member 214, and the guide hole 216 is arranged in the guide member 214.

In the above embodiment, the guide post 116 can in contact with the bottom wall of the guide hole 216. It should be noted that the bottom wall of the guide hole 216 is in contact with the guide post 116 when the first cabinet main body is in the hanging fixing position 01. In this way, the positioning of the second cabinet 2 to the first cabinet main body is realized, which ensures that the first cabinet main body reaches the hanging fixing position 01, and also ensures that the first connection terminal 15 is plugged in place to the second connection terminal 25.

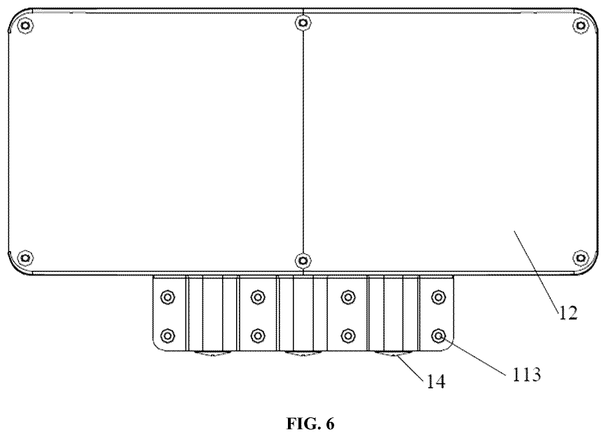

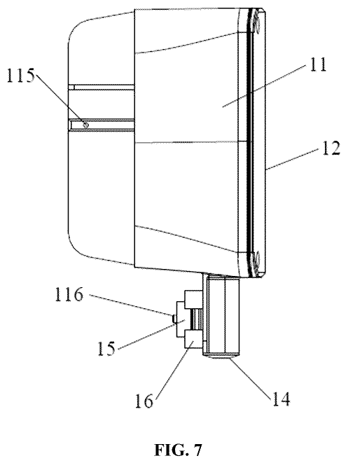

The specific structure of the first cabinet main body is determined based on the actual situation. In some embodiments, as shown in FIG. 1 to FIG. 3, the first cabinet main body includes a first cabinet housing 11 and a first cabinet cover plate 12, and one side of the first cabinet housing 11 is connected to a first hanging plate 13, and the other side of the first cabinet housing 11 is fixedly connected to the first cabinet cover plate 12. As shown in FIG. 7, FIG. 8 and FIG. 10, the first connection terminal 15 is arranged in the first cabinet housing 11, and as shown in FIG. 6 to FIG. 10, the first cabinet housing 11 has a first wiring hole 112 through which the first cable 158 passes and a first blocking member 14 for sealing the first wiring hole 112.

It should be noted that the first cabinet housing 11 is hermetically connected to the first cabinet cover plate 12. For example, the first cabinet housing 11 is hermetically connected to the first cabinet cover plate 12 through a sealing member, which is arranged outside the first cabinet housing 11 or the first cabinet cover plate 12.

The first connection terminal 15 is hermetically connected to the first cabinet housing 11. For example, as shown in FIG. 4, the first connection terminal 15 is hermetically connected with the first cabinet housing 11 through a first end face sealing ring 155. The specific way of sealing connection is determined based on the actual situation, which is not limited in this embodiment.

In a case that the first cabinet 1 and the second cabinet 2 are sequentially distributed in the vertical direction, and the first cabinet 1 is located higher than the second cabinet 2, the first connection terminal 15 is arranged at a bottom end of the first cabinet housing 11, and the second connection terminal 25 is arranged at a top end of the second cabinet 2.

As shown in FIG. 6 to FIG. 11, the first cabinet housing 11 is provided with a first blocking member mounting surface 111, a first wiring hole 112, a slideway hole 114, a first hanging plate fixing hole 115, a guide post 116, a first mounting post 16, a first connection terminal mounting hole 119 and a first connection terminal fixing hole 120. The first blocking member 14 is mounted on the first blocking member mounting surface 111 and seals the first wiring hole 112. The first mounting post 16 is provided with a first mounting hole 113 and a positioning hole 117. The first connection terminal 15 is mounted in the first connection terminal mounting hole 119 and is fixed to the first cabinet housing 11 through the first connection terminal fixing hole 120. The first hook 134 of the first hanging plate 13 is hung and fitted with the slideway hole 114, and the first hanging plate 13 is fixed at the first hanging plate fixing hole 115.

It should be noted that an aperture of the first mounting hole 113 is smaller than that of the positioning hole 117, and the first mounting hole 113 is farther away from the second mounting post 215 than the positioning hole 117.

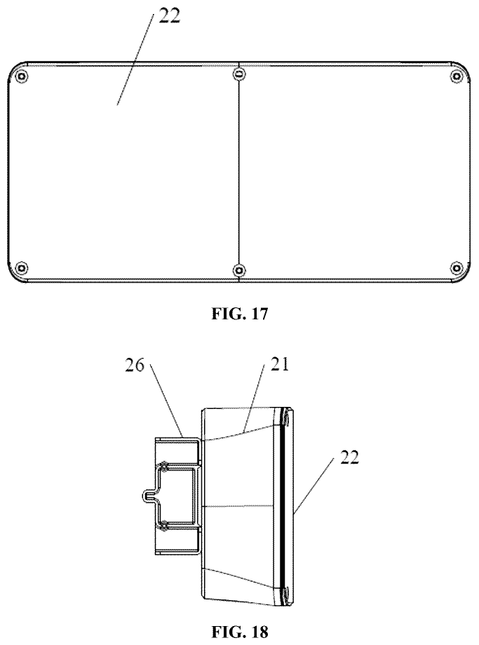

The specific structure of the second cabinet 2 is determined based on the actual situation. In some embodiments, as shown in FIG. 1 and FIG. 2 as well as FIG. 17 to FIG. 19, the second cabinet 2 includes a second cabinet housing 21 and a second cabinet cover plate 22, where one side of the second cabinet housing 21 is configured to be fixed on the mounting surface, and the other side of the second cabinet housing 21 is fixedly connected to the second cabinet cover plate 22. As shown in FIG. 4, the second connection terminal 25 is arranged in the second cabinet housing 21, and the second connection terminal 25 is hermetically connected to the second cabinet housing 21 through a second end face sealing ring 255.

It should be noted that the second cabinet housing 21 may be fixed on the mounting surface directly or through the second hanging plate 23. The second cabinet housing 21 is hermetically connected to the second cabinet cover plate 22. For example, the second cabinet housing 21 is hermetically connected to the second cabinet cover plate 22 through a sealing member, which is arranged on the second cabinet housing 21 or the second cabinet cover plate 22.

In a case that the second cabinet housing 21 is fixed to the mounting surface through the second hanging plate 23, as shown in FIG. 18 and FIG. 19, the second cabinet housing 21 may be provided with a cabinet bracket 26, which is located on the side, away from the second cabinet cover plate 22, of the second cabinet housing 21, and is configured for connecting to the second hanging plate 23. In this case, as shown in FIG. 26 to FIG. 28, the cabinet bracket 26 is provided with a cabinet mounting surface 261 in contact with the second cabinet housing 21, a cabinet mounting hole 262 fixedly connected with the second cabinet housing 21, a supporting surface 263 in contact with the mounting surface, a second hanging plate mounting hole 264 fixedly connected with the second hanging plate 23, and a hanging hole 265 in hanging fit with the second hanging plate 23.

The second cabinet housing 21 and the cabinet bracket 26 may be of an integrated structure or separated structures, which can be determined in a basis of the actual situation and is not limited by the embodiment of the application.

As shown in FIG. 19 to FIG. 23, the second cabinet housing 21 is provided with a second blocking member mounting surface 211, a second wiring hole 212, a bracket mounting hole 213, a guide member 214, a second mounting post 215, a second connection terminal mounting hole 219, and a second connection terminal fixing hole 220. The second blocking member 24 is mounted on the second blocking member mounting surface 211 and seals the second wiring hole 212. The cabinet bracket 26 is mounted at the bracket mounting hole 213. The guide member 214 is provided with the guide hole 216. The second mounting post 215 is provided with a second mounting hole 217, and a free end surface of the second mounting post 215 is a post end face 218, which can contact with the positioning hole bottom wall 118 of the positioning hole 117. The second connection terminal 25 is mounted at the second connection terminal mounting hole 219 and is fixed to the second cabinet housing 21 through the second connection terminal fixing hole 220.

In some embodiments, in order to improve structural compactness of the inverter, one of the first cabinet 1 and the second cabinet 2 is embedded in the other of the first cabinet 1 and the second cabinet 2.

The first cabinet 1 includes a first cabinet main body, on which the first connection terminal 15 is arranged, and the second cabinet body 2 includes a second cabinet main body, on which the second connection terminal 25 is arranged. In order to facilitate embedding of the first cabinet 1 and the second cabinet 2, one of the first cabinet main body and the second cabinet main body can be selected to be embedded in the other of the first cabinet main body and the second cabinet main body. For example, the first cabinet main body is embedded in the second cabinet main body, or the second cabinet main body is embedded in the first cabinet main body.

In the above-mentioned embodiment, in order to improve a protection performance, the first cabinet main body has a cabinet connecting part for mounting the first connection terminal 15, and both the cabinet connecting part and the first connection terminal 15 are embedded in the second cabinet main body.

It can be understood that the second cabinet main body has an accommodation space for accommodating the first connection terminal 15 and the cabinet connecting part.

In a case that the second cabinet main body includes a second cabinet housing 21 and a second cabinet cover plate 22, both the first connection terminal 15 and the cabinet connecting part are embedded in the second cabinet housing 21, that is, the accommodation space is located in the second cabinet housing 21. The accommodation space may be located at a side, near the second cabinet cover plate 22, of the second cabinet housing 21, or the accommodation space may be located at a side, away from the second cabinet cover plate 22, of the second cabinet housing 21. In order to simplify the mounting, former arrangement is preferred.

In the above-mentioned embodiment, in order to improve the stability of the plugging connection between the first connection terminal 15 and the second connection terminal 25, the cabinet connecting part may be fixedly connected with the second cabinet main body.

In the case that the second cabinet main body includes the second cabinet housing 21 and the second cabinet cover plate 22, the cabinet connecting part and the second cabinet housing 21 are fixedly connected with each other. In order to facilitate the fixed connection between the cabinet connecting part and the second cabinet housing 21, the side, away from the mounting surface, of the second cabinet housing 21 can be selected to have a mounting port for fixedly connecting the cabinet connecting part and the second cabinet housing 21, and the second cabinet cover plate 22 closes the mounting port.

In the actual mounting process, it is possible to fix the cabinet connecting part and the second cabinet housing 21 first, and then fix the second cabinet cover plate 22 to the second cabinet housing 21. In this way, the cabinet connecting part and the second cabinet housing 21 can be fixedly connected with each other at the side opposite to the mounting surface, which can provide a relatively large mounting space without increasing the volume of the second cabinet 2, and thus facilitates the miniaturization of the second cabinet 2. Moreover, the visual operation is realized and the customer experience and assembly efficiency are improved.

In order to facilitate disassembling the first cabinet 1, the second cabinet housing 21 and the second cabinet cover plate 22 may be detachably connected with each other, and the cabinet connecting part and the second cabinet housing 21 may be detachably connected with each other.

In other embodiments, it is also possible that the first cabinet main body is not embedded in the second cabinet main body, and the second cabinet main body is not embedded in the first cabinet main body, that is, the whole first cabinet main body is located outside the second cabinet main body, and the whole second cabinet main body is located outside the first cabinet main body. In this case, the first connection terminal 15 may extend out of the first cabinet main body or the first connection terminal 15 may be arranged outside the first cabinet main body, and the second connection terminal 25 may extend out of the second cabinet main body or the second connection terminal 25 may be arranged outside the second cabinet main body. In this way, the first connection terminal 15 and the second connection terminal 25 are plugged with each other outside the first cabinet main body and the second cabinet main body.

In other embodiments, it is also possible to arrange the first cabinet main body and the second cabinet main body in other ways, which is not limited in this embodiment of the application.

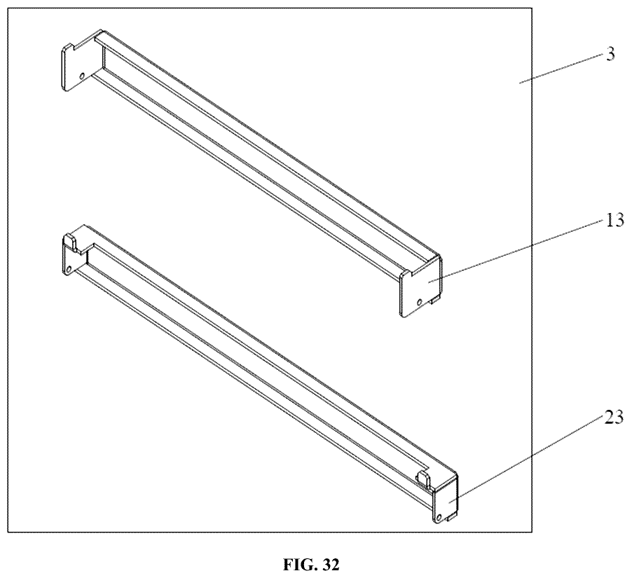

In order to explain the inverter provided in the above embodiment more clearly, a method for mounting the inverter is provided below with reference to FIG. 32 to FIG. 36. In this method, the first cabinet 1 and the second cabinet 2 are not assembled together in advance, and the first cabinet 1 and the second cabinet 2 are hung separately.

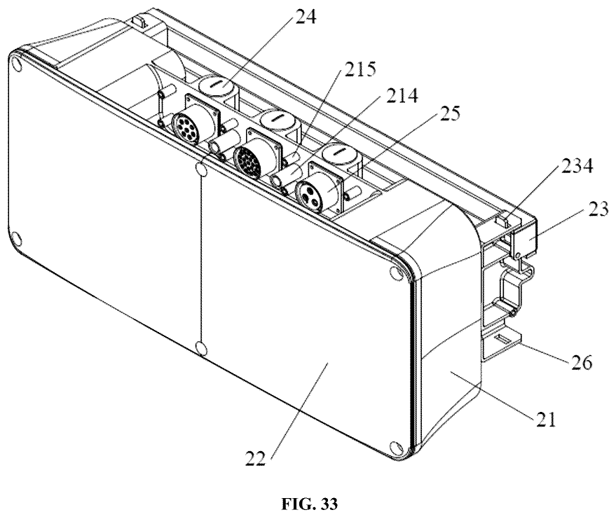

The method for mounting the inverter is as follows.
S1: as shown in FIG. 32, fixing the first hanging plate 13 and the second hanging plate 23 respectively on the mounting surface 3;
S2: as shown in FIG. 33, hanging and fixing the second cabinet housing 21 with the second cabinet cover plate 22 on the second hanging plate 23;
S3, removing the second cabinet cover plate 22;
S4: As shown in FIG. 34 and FIG. 35, hanging the first cabinet main body (the first cabinet housing 11 and the first cabinet cover plate 12) on the first hanging plate 13, and the first cabinet main body is located at the hanging position 02;
S5, moving the first cabinet main body to the hanging fixing position 01 in a direction close to the mounting surface 3;
S6, fixedly connecting the first cabinet housing 11 with the second cabinet housing 21;
S7, fixedly connecting the first cabinet housing 11 to the first hanging plate 13;
S8: fixedly connecting the second cabinet cover plate 22 to the second cabinet housing.

In S1, that fixing the first hanging plate 13 and the second hanging plate 23 respectively on the mounting surface 3 specifically includes fixing the first hanging plate 13 first and then fixing the second hanging plate 23, or fixing the second hanging plate 23 first and then fixing the first hanging plate 13.

In S1, a preset distance is provided between the first hanging plate 13 and the second hanging plate 23 to ensure the mounting of the first cabinet main body and the second cabinet main body.

In S2, that hanging and fixing the second cabinet housing 21 with the second cabinet cover plate 22 on the second hanging plate 23 specifically includes enabling the second hooks 234 on the second hanging plate 23 passing through the hanging holes 265 on both sides of the second cabinet main body, and thus the supporting surface 263 of the second cabinet main body abutting against the mounting surface 3, and enabling the bolts passing through the fourth connecting holes 233 and the second hanging plate mounting holes 264 to fasten the bolts.

In S2, that hanging and fixing the second cabinet main body on the second hanging plate 23 specifically includes hanging and fixing only the second cabinet housing 21 on the second hanging plate 23. In this case, S3 may be omitted.

In S4, the first hook 134 passes through the slideway hole 114. At this time, the first hook 134 is located at one end of the slideway hole 114, so that the first cabinet main body is located away from the mounting surface, the second cabinet housing 21 is located in front of the first cabinet housing 11, and the first cabinet main body is in the suspension position 02.

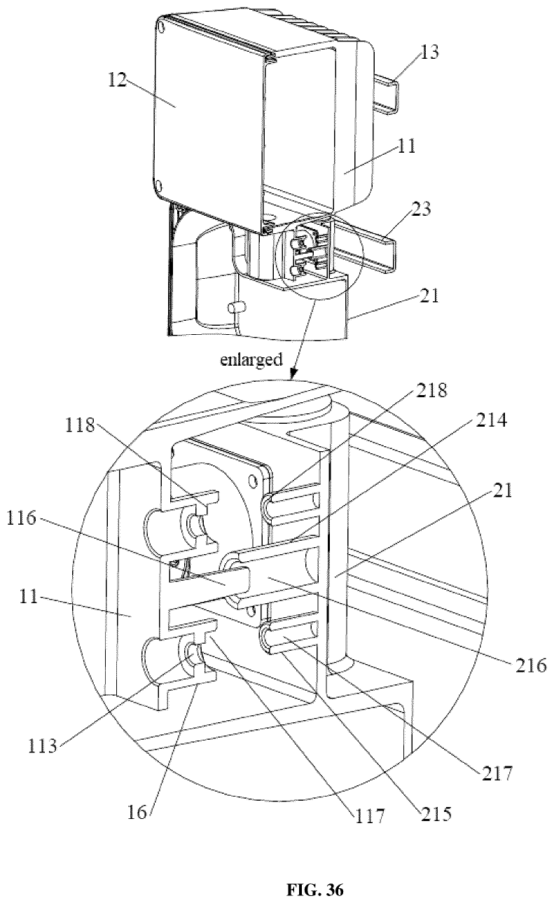

In S4, the first cabinet main body is hung on the first hanging plate 13 and located at the hanging position 02. In this case, as shown in FIG. 36, the guide post 116 extends into the guide hole 216, and a preset distance is provided between the first mounting post 16 and the second mounting post 215.

In S5, the first cabinet main body is pushed to the mounting surface 3 from the side away from the mounting surface 3. Under the guidance of the guide post 116 and the guide hole 216, the relative position of the slideway hole 114 and the first hook 134 changes, so that the first cabinet main body reaches the hanging fixing position 01. After the second mounting post 215 enters into the positioning hole 117, the positioning hole bottom wall 118 approaches the post end face 218 of the second mounting post 215.

In S6, the bolts can be used to fit into the first mounting hole 113 and the second mounting hole 217 from the side, away from the mounting surface 3, of the first cabinet main body for fastening connection. The first connection terminal 15 and the second connection terminal 25 are plugged with each other during the positioning and fastening, and the terminal pin 153 is inserted into the terminal socket 253 to form a reliable connection. The interface sealing ring 156 on the first connection terminal 15 forms a seal with the second connection terminal 25.

After S6 is completed, the sealed connection between the first cabinet housing 11 and the second cabinet housing 21 is realized.

In S7, the bolts can be used to pass through the second connecting holes 135 on both sides of the first hanging plate 13 and the first hanging plate fixing holes 115 for fastening connection.

It should be noted that a region of the mounting surface 3 shown in FIG. 32 is only an illustration, and size of the mounting surface 3 may be adjusted at will.

FIG. 1 to FIG. 5 show the mounted inverter. As shown in FIG. 1 to FIG. 5, in the mounted inverter, the first cabinet main body is located at the hanging fixing position 01. The terminal pin 153 of the first connection terminal 15 is inserted into the terminal socket 253 of the second connection terminal 25, and the first connection terminal 15 is plugged in place. The post end face 218 of the second mounting post 215 abuts against the positioning hole bottom wall 118 of the positioning hole 117.

After the inverter is mounted, the whole inverter has a sealed structure, that is, the first cabinet 1 and the second cabinet 2 form a sealed structure.

In a case that the structure of the inverter provided in the above embodiment changes, the method for mounting the inverter can be adaptively adjusted.

In a case that the first cabinet main body needs to be replaced, the second cabinet cover plate 22, the bolts on the first mounting hole 113 and the bolts on both sides of the first hanging plate 13 are removed. Then, the first cabinet main body to the side is moved away from the mounting surface 3 in the horizontal direction, and the first cabinet main body is lifted upwards. Finally, a new first cabinet main body is mounted. For the specific method of mounting the new first cabinet main body, please refer to the method for mounting the inverter mentioned above, which is not be repeated here.

In other embodiments, the first cabinet main body is directly fixed on the mounting surface, and in this case, the first cabinet main body 1 does not include the first hanging plate 12.

In this embodiment, the first connection terminal 15 and the second connection terminal 25 are configured for plugging along the direction that the first cabinet main body moves to the mounting surface, and the first connection terminal 15 and the second connection terminal 25 are plugged with each other when the first cabinet main body is located on the mounting surface.

It should be noted that the direction in which the first cabinet main body moves to the hanging fixing position 01 and the direction in which the first cabinet main body moves to the mounting surface can both be called as the direction of the first cabinet main body 1 moving to the mounting surface. The first hanging plate 13 is fixed on the mounting surface, the first cabinet main body is located at the hanging fixing position 01, and the first cabinet main body is located on the mounting surface, all of which can be called that the first cabinet main body 1 is located on the mounting surface.

In this embodiment, the method for mounting the inverter is as follows: firstly fixing the second cabinet 2 on the mounting surface, then moving the first cabinet 1 to the mounting surface, and the first connection terminal 15 of the first cabinet 1 getting close to the second connection terminal 25 of the second cabinet 2 during the movement. When the first cabinet 1 is moved to the mounting surface, the first connection terminal 15 and the second connection terminal 25 are plugged with each other, that is, when the first cabinet 1 is located on the mounting surface, the first connection terminal 15 and the second connection terminal 25 are plugged with each other, and finally the first cabinet 1 is fixed on the mounting surface.

According to the above mounting method, the first connection terminal 15 and the second connection terminal 25 are plugged with the each other when the first cabinet 1 moves to the mounting surface, and there is no need to plug the first connection terminal 15 to the second connection terminal 25 separately, which effectively simplifies the assembly of the first cabinet 1 and the second cabinet 2, thus simplifying the mounting of the inverter.

In this embodiment, other structures of the inverter can make reference to the foregoing description, which is not described here.

Based on the inverter provided in the above embodiment, a photovoltaic and energy storage system is further provided according to the embodiment of the application, which includes the inverter as described in the above embodiment.

Since the inverter provided in the above embodiment has above technical effects, and the photovoltaic and energy storage system includes the inverter described above, the above photovoltaic and energy storage system also has corresponding technical effects, which will not be described in detail here.

The photovoltaic and energy storage system may be a power generation system, an energy storage system, and may also include a power generation system and an energy storage system. The specific type of photovoltaic and energy storage system can be determined based on the actual situation, which is not limited in this embodiment.

The above illustration of the disclosed embodiments can enable those skilled in the art to implement or use the application. Various modifications made to these embodiments are apparent for those skilled in the art, and the general principle defined herein may be implemented in other embodiments without departing from spirit or scope of the application. Therefore, the application is not limited to the embodiments described herein, but should be in accordance with the broadest scope consistent with the principle and novel features disclosed herein.

1. An inverter, comprising:
a first cabinet for being fixed on a mounting surface;
a second cabinet for being fixed on the mounting surface;
wherein the first cabinet is provided with a first connection terminal, the second cabinet is provided with a second connection terminal, the first connection terminal and the second connection terminal are configured for plugging along a direction in which the first cabinet moves to the mounting surface, and the first connection terminal and the second connection terminal are plugged with each other when the first cabinet is located on the mounting surface.

2. The inverter according to claim 1, wherein the first cabinet comprises a first hanging plate and a first cabinet main body, the first hanging plate is configured for being fixed on the mounting surface, the first hanging plate is provided with a hanging fixing position for hanging and fixing the first cabinet main body, and the first connection terminal is arranged on the first cabinet main body;
wherein that the direction in which the first cabinet moves to the mounting surface means the first cabinet main body moves to a direction of the hanging fixing position;
that the first cabinet is located on the mounting surface means the first hanging plate is fixed on the mounting surface and the first cabinet main body is located at the hanging fixing position.

3. The inverter according to claim 2, wherein
the first hanging plate further has a hanging position only for hanging the first cabinet main body, and the first cabinet main body is movable between the hanging position and the hanging fixing position;
the first connection terminal and the second connection terminal are configured for plugging along a direction in which the first cabinet main body moves from the hanging position to the hanging fixing position.

4. The inverter according to claim 3, wherein one of the first cabinet main body and the first hanging plate is provided with a slideway hole, and the other of the first cabinet main body and the first hanging plate is provided with a first hook which is in sliding fit with the slideway hole;
wherein when one end of the slideway hole is in contact with the first hook, the first cabinet main body is in the hanging position, and when the other end of the slideway hole is in contact with the first hook, the first cabinet main body is in the hanging fixing position.

5. The inverter according to claim 2, wherein when the first cabinet main body is in the hanging fixing position, the first cabinet main body is detachably connected with the first hanging plate; and the first connection terminal is detachably plugged with the second connection terminal.

6. The inverter according to claim 1, wherein one of the first cabinet and the second cabinet is provided with a positioning post and the other of the first cabinet and the second cabinet is provided with a positioning hole; the positioning post is fitted with the positioning hole and is in contact with a bottom wall of the positioning hole, and an axial direction of the positioning post is parallel to a plugging direction of the first connection terminal and the second connection terminal.

7. The inverter according to claim 1, wherein when the first cabinet is located on the mounting surface, the first cabinet is fixedly connected with the second cabinet by a fastener, and an axial direction of the fastener is parallel to the plugging direction of the first connection terminal and the second connection terminal.

8. The inverter according to claim 7, wherein the first cabinet is provided with a first mounting post, and the second cabinet is provided with a second mounting post;
wherein the first mounting post and the second mounting post each is provided with a mounting hole for mounting the fastener; one of the first mounting post and the second mounting post is provided with a positioning hole, and the other of the first mounting post and the second mounting post is fitted with the positioning hole and is in contact with a bottom wall of the positioning hole.

9. The inverter according to claim 1, wherein one of the first cabinet and the second cabinet is provided with a guide post and the other of the first cabinet and the second cabinet is provided with a guide hole; wherein the guide post and the guide hole are configured for guiding and fitting in the plugging direction of the first connection terminal and the second connection terminal.

10. The inverter according to claim 1, wherein the first cabinet comprises a first cabinet main body, on which the first connection terminal is arranged; and the second cabinet comprises a second cabinet main body, on which the second connection terminal is arranged;
wherein one of the first cabinet main body and the second cabinet main body is embedded in the other of the first cabinet main body and the second cabinet main body; or the first cabinet main body is entirely located outside the second cabinet main body, and the second cabinet main body is entirely located outside the first cabinet main body.

11. The inverter according to claim 10, wherein when one of the first cabinet main body and the second cabinet main body is embedded in the other of the first cabinet main body and the second cabinet main body, the first cabinet main body has a cabinet connecting part for mounting the first connection terminal, and both the cabinet connecting part and the first connection terminal are embedded in the second cabinet main body, and the cabinet connecting part and the second cabinet main body are fixedly connected with each other.

12. The inverter according to claim 11, wherein the second cabinet main body comprises:
a second cabinet housing for fixing on the mounting surface, wherein the second connection terminal is arranged in the second cabinet housing, the cabinet connecting part is fixedly connected with the second cabinet housing, and a side, away from the mounting surface, of the second cabinet housing is provided with a mounting port for fixedly connecting the cabinet connecting part and the second cabinet housing; and
a second cabinet cover plate, wherein the second cabinet cover plate is fixed on the second cabinet housing, and the second cabinet cover plate closes the mounting port.

13. The inverter according to claim 12, wherein the second cabinet housing and the second cabinet cover plate are detachably connected with each other, and the cabinet connecting part and the second cabinet housing are detachably connected with each other.

14. The inverter according to claim 1, wherein the first cabinet comprises a first cabinet housing and a first cabinet cover plate, wherein one side of the first cabinet housing is opposite to the mounting surface, and the other side of the first cabinet housing is fixedly connected with the first cabinet cover plate;
wherein the first connection terminal is arranged in the first cabinet housing, and the first cabinet housing is provided with a first wiring hole for a first cable to pass through and a first blocking member for sealing the first wiring hole.

15. The inverter according to claim 1, wherein the second cabinet comprises a second cabinet main body and a second hanging plate, wherein the second hanging plate is configured for being fixed on the mounting surface, and the second cabinet main body is configured for being hung and fixed on the second hanging plate;
wherein the second connection terminal is arranged on the second cabinet main body, and the second cabinet main body is provided with a second wiring hole for a second cable to pass through and a second blocking member for sealing the second wiring hole.

16. The inverter according to claim 15, wherein
the first cabinet comprises a first hanging plate and a first cabinet main body, wherein the first hanging plate is configured for being fixed on the mounting surface and is provided with a hanging fixing position for hanging and fixing the first cabinet main body, and the first connection terminal is arranged on the first cabinet main body;
that the direction in which the first cabinet moves to the mounting surface means the first cabinet main body moves to a direction of the hanging fixing position;
that the first cabinet is located on the mounting surface means the first hanging plate is fixed on the mounting surface and the first cabinet main body is located at the hanging fixing position;
wherein the second hanging plate and the first hanging plate have an integrated structure or a separated structure.

17. The inverter according to claim 1, wherein
the plugging direction of the first connection terminal and the second connection terminal is perpendicular to the mounting surface;
and/or the first cabinet and the second cabinet are sequentially distributed in a vertical direction;
and/or the first connection terminal and the first cabinet are hermetically connected with each other, the second connection terminal and the second cabinet are hermetically connected with each other, and the first connection terminal and the second connection terminal are hermetically connected with each other.

18. A photovoltaic and energy storage system, comprising the inverter according to claim 1.
